(19) United States
(12) Patent Application Publication
(10) Pub. No.: US 2013/0047877 A1
(43) Pub. Date: Feb. 28, 2013

(54) SQUEEZE APPARATUS

(71) Applicants: Cheol Jun YOO, Chungcheongnam-do (KR); Min Jung KIM, Gyunggi-do (KR)

(72) Inventors: Cheol Jun YOO, Chungcheongnam-do (KR); Min Jung KIM, Gyunggi-do (KR)

(21) Appl. No.: 13/595,468

(22) Filed: Aug. 27, 2012

(30) Foreign Application Priority Data
Aug. 25, 2011 (KR) 10-2011-0084999

(51) Int. Cl. B41F 31/08

(52) U.S. Cl. 101/364

(57) ABSTRACT

A squeeze apparatus includes a body unit and an injection unit. The body unit has a flow path inside the body unit for applying a printing substance on a substrate. The injection unit has a nozzle that fluidly communicates with the flow path to inject the printing substance. The nozzle has a curved surface facing the substrate.

### CROSS-REFERENCE TO RELATED APPLICATION

This U.S. non-provisional application claims benefit of priority to Korean Patent Application No. 10-2011-0084999, filed on Aug. 25, 2011, in the Korean Intellectual Property Office, the entirety of which is hereby incorporated by reference.

### BACKGROUND

1. Field

The present invention relates to a squeeze apparatus for applying a printing substance on a substrate, and more particularly, to a squeeze apparatus having improved print quality by preventing interference between a squeeze member and a substrate or a mask, while performing a squeezing operation.

2. Description of the Related Art

A squeeze apparatus is used to form an electrode and a bump, or to apply a fluorescent substance and the like, in a process for manufacturing a solar cell, a substrate, and a light emitting diode (LED) package. The squeeze apparatus may lay, on a substrate, a mask that is patterned with a desired pattern, and may apply, using a pressure, a predetermined printing substance to an opening of the mask so as to print the desired pattern on the substrate. Here, the mask may be a metal mask or a mesh mask.

When the squeeze apparatus applies the printing substance to the substrate, interference may occur in a nozzle due to an uneven surface of the substrate or the mask. The interference may cause deterioration in print quality, or may cause damage to the nozzle, the substrate, and/or the mask. Accordingly, a desire exists for continuous research and development to prevent interference while the squeeze apparatus operates, so as to improve a print quality.

### SUMMARY

An aspect of the present disclosure encompasses a squeeze apparatus that may adjust a diameter of a nozzle through which a printing substance is injected.

Another aspect of the present disclosure relates to a squeeze apparatus including a body unit and an injection unit. The body unit may include a flow path inside the body unit for applying a printing substance on a substrate. The injection unit may have a nozzle that fluidly communicates with the flow path to inject the printing substance. The nozzle has a curved surface facing the substrate.

The body unit may have a cylinder-shaped receiving space connected to the flow path to receive the printing substance, and may inject the printing substance via the nozzle by a supply force of the printing substance received by the receiving space.

The body unit may include a receiving space connected to the flow path to receive the printing substance, and a pressure unit configured to press the printing substance received by the receiving space in a direction toward the nozzle.

At least one of the body unit and the pressure unit may include a supply path fluidly communicating with the receiving space for supplying the printing substance.

The injection unit may be configured be moveable with respect to the body unit to adjust an amount of the printing substance injected via the nozzle.

The injection unit may include a pair of squeeze members facing each other and movable with respect to the body unit. The injection unit may also include an adjusting member to adjust an interval between the pair of squeeze members by moving the pair of squeeze members with respect to the body unit.

The body unit may include a pair of bodies connectable with each other to provide a receiving space to receive the printing substance. The pair of bodies includes receiving grooves on facing surfaces thereof. The injection unit may include a pair of squeeze members respectively connectable with the pair of bodies, and an adjusting member to adjust an interval between the pair of squeeze members by adjusting an interval between the pair of bodies.

The body unit may include a pair of bodies facing each other and having an interval therebetween to form the flow path for the printing substance. The injection unit may include a pair of squeeze members respectively connectable with the pair of bodies. Each squeeze member may have a cylindrical shape of which a cross section has a circular shape or a semi-circular shape.

The body unit may include a pair of bodies facing each other and having an interval therebetween to form the flow path for the printing substance. The injection unit may include a pair of squeeze members respectively connectable with the pair of bodies. Each squeeze member may have a cylindrical shape of which a cross section is a semi-circular shape. An end portion of each squeeze member facing the substrate may have a rounded shape in a direction toward an internal region of the nozzle.

The body unit may include a pair of bodies facing each other and having an interval between thereof to form the flow path for the printing substance. The injection unit may include a pair of squeeze members respectably connectable with the pair of bodies. Each squeeze member may have a cylindrical shape of which an end portion faces the substrate and has a curved surface.

The injection unit may include a mesh member disposed in the nozzle.

An aspect of the present disclosure encompasses a squeeze apparatus including a body unit and an injection unit. The body unit may include a flow path inside the body unit for applying a printing substance to a substrate. The injection unit may have a pair of squeeze members to inject the printing substance. The pair of squeeze members are disposed in the body unit and have an interval between the pair of squeeze members to form a nozzle that fluidly communicates with the flow path. Each squeeze member may have a curbed surface facing the substrate.

The body unit may include a pair of bodies. The pair of bodies may include a pair of squeeze members respectively disposed therein, and has receiving grooves in facing surfaces thereof to form a receiving space for receiving the printing substance. The pair of bodies may be connectable with each other. The printing substance may be injected via the nozzle by a supply force of the printing substance received by the receiving space.

The body unit may include a pair of bodies and a pressure unit. The pair of bodies may include a pair of squeeze members respectively disposed in the pair of bodies, and has receiving grooves in facing surfaces thereof to form a receiving space for receiving the printing substance. The pair of bodies may be connectable with each other. The pressure unit is configured to press the printing substance received by the receiving space in a direction toward the nozzle.

At least one of the body unit and the pressure unit may include a supply path fluidly communicating with the receiving space for supplying the printing substance.

The pair of squeeze members may be configured to adjust the interval therebetween with respect to the body unit, so that an amount of the printing substance injected via the nozzle is adjusted.

The body unit may include a pair of bodies. The pair of bodies may include a pair of squeeze members respectively disposed in the pair of bodies, have receiving grooves on facing surfaces thereof to form a receiving space for receiving the printing substance, and be connectable with each other. The injection unit may include an adjusting member that adjusts an interval between the pair of bodies to adjust the interval between the pair of squeeze members.

Each squeeze member may have a cylindrical shape of which a cross section has a circular shape or a semi-circular shape.

Each squeeze member may have a cylindrical shape of which a cross section is a semi-circular shape. An end portion of each squeeze member facing the substrate may have a rounded shape in a direction toward an internal region of the nozzle.

Each squeeze member may have a cylindrical shape of which an ending portion faces the substrate and has a curved surface.

The injection unit may include a mesh member disposed between the pair of squeeze members.

Yet another aspect of the present disclosure relates to a squeeze apparatus including a body unit and an injection unit. The body unit may have a flow path inside the body unit for applying a printing substance to a substrate. The injection unit may include a pair of squeeze members and be configured to inject the applied printing substance. The squeeze members may have an interval therebetween to form a nozzle that fluidly communicates with the flow path, and may be configured to adjust the interval therebetween so that an amount of the printing substance injected via the nozzle is adjusted.

Each of the squeeze members may have a curved surface facing the substrate. The nozzle may have a curved surface facing the substrate.

Embodiments of the present disclosure may include a nozzle having a curved-shaped surface and thus, may prevent interference between the nozzle and a substrate or a mask during an injection operation. Accordingly, damage in the nozzle may be prevented and print quality may be improved.

Embodiments of the present disclosure may adjust an interval between a pair of squeeze members that are connected with each other to form a nozzle and thus, may adjust an amount of a printing substance that is injected based on a printing environment or a viscosity of the printing substance.

Embodiments of the present disclosure may include a mesh member disposed in a nozzle and thus, may apply, with a uniform discharge pressure, a printing substance to a three-dimensional surface without a void.

### BRIEF DESCRIPTION OF THE DRAWINGS

The foregoing and other features of the present disclosure will be apparent from more particular description of embodiments of the present disclosure, as illustrated in the accompanying drawings in which like reference characters may refer to the same or similar parts throughout the different views. The drawings are not necessarily to scale, emphasis instead being placed upon illustrating the principles of the embodiments of the present disclosure. In the drawings, the thickness of layers and regions may be exaggerated for clarity.

FIG. 1 is an exploded perspective view of a squeeze apparatus according to an embodiment of the present disclosure:

FIG. 2 is a cross-sectional view of the squeeze apparatus of FIG. 1;

FIG. 3 is a cross-sectional view of a modified squeeze apparatus including a pressure unit according to an embodiment of the present disclosure;

FIG. 4 is a cross-sectional view of the squeeze apparatus of FIG. 3 to which a printing substance is being supplied;

FIG. 5 is a cross-sectional view of a modified squeeze apparatus including a supply path formed in a pressure unit according to an embodiment of the present disclosure;

FIG. 6 is a cross-sectional view of the squeeze apparatus of FIG. 5 to which a printing substance is being supplied;

FIG. 7 is a cross-sectional view of a squeeze apparatus according to another embodiment of the present disclosure:

FIG. 8 is an exploded perspective view of a squeeze apparatus according to still another embodiment of the present disclosure;

FIG. 9 is a cross-sectional view of the squeeze apparatus of FIG. 8;

FIG. 10 is a cross-sectional view of a modified squeeze member according to an embodiment of the present disclosure:

FIG. 11 is an exploded perspective view of a squeeze apparatus according to yet another embodiment of the present disclosure:

FIG. 12 is a perspective view of an assembly state of the squeeze apparatus of FIG. 11;

FIG. 13 is an expanded cross-sectional view of the squeeze member of FIG. 12;

FIG. 14 is a cross-sectional view of a modified squeeze member that is modified from the squeeze member of FIG. 13; and

FIG. 15 is a cross-sectional view of a squeeze apparatus according to a further embodiment of the present disclosure.

### DETAILED DESCRIPTION

Exemplary embodiments of the present disclosure will be described below in more detail with reference to the accompanying drawings. The embodiments of the present disclosure may, however, be embodied in different forms and should not be construed as limited to the embodiments set forth herein. Like reference numerals may refer to like elements throughout the specification.

In the drawings, the thickness of layers and regions may be exaggerated for clarity. It will also be understood that when an element such as a layer, region or substrate is referred to as being “on” or “onto” another element, it may lie directly on the other element or intervening elements or layers may also be present.

Hereinafter, referring to the drawings, the embodiments of the present disclosure will be described in further detail.

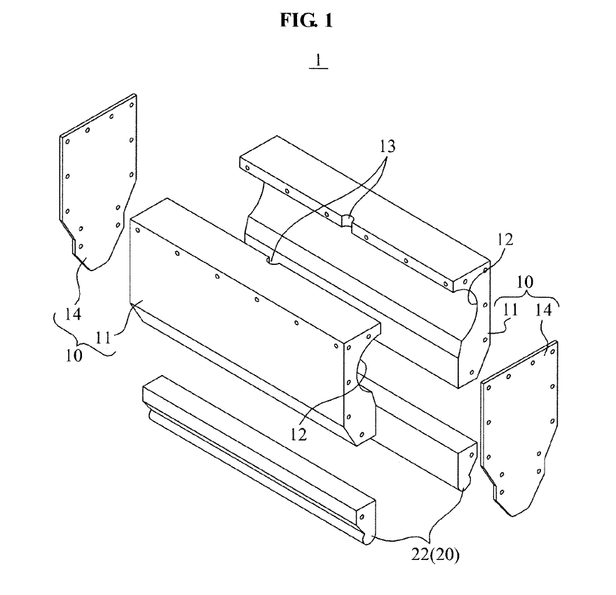

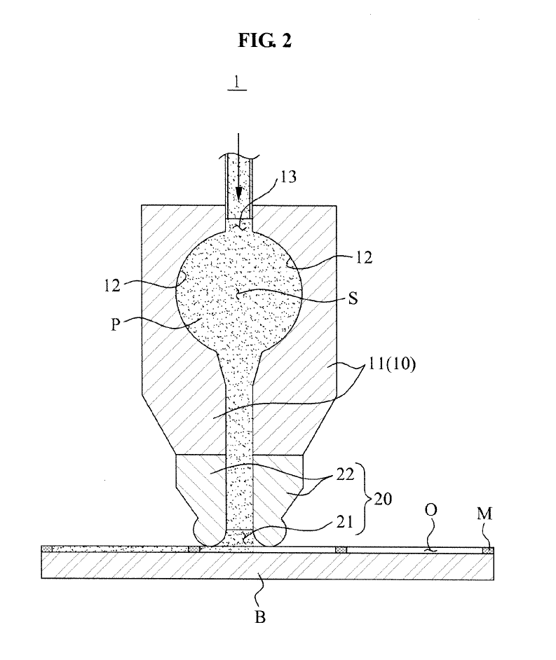

FIG. 1 is an exploded perspective view of a squeeze apparatus 1 according to an embodiment of the present disclosure, and FIG. 2 is a cross-sectional view of the squeeze apparatus 1 of FIG. 1.

Referring to FIG. 1, the squeeze apparatus 1 includes a body unit 10 and an injection unit 20.

Referring to FIGS. 1 and 2, the body unit 10 may include, inside the body unit 10, a flow path for a printing substance P to be applied to a substrate B. The body unit 10 may include a pair of bodies 11 and a pair of covers 14 that cover both ends of the pair of bodies 11.

As illustrated in FIG. 2, to form a receiving space S to receive the printing substance, receiving grooves 12 may be respectively formed on facing surfaces of the pair of bodies 11. Each of the receiving grooves 12 formed on a respective one of the bodies 11 may be provided in a substantially semi-circular shape. Thus, the receiving space S may be provided in a shape of a cylinder. Since a cylinder-shaped receiving space S is formed, an internal pressure in the receiving space S may be adjusted to be uniform and thereby minimize a loss of the printing substance P.

A supply path 13 may be formed in the body 11 to fluidly communicate with the receiving grooves 12 so as to provide the printing substance P. Although is it not separately illustrated, the supply path 13 is connected with a supplying unit provided outside the body unit 10 to receive the printing substance P. The supply unit may be an additional supplying chamber, a supplying motor, and the like.

Inside the body unit 10, the receiving space S is formed by the receiving grooves 12, and the supply path 13 is formed through the pair of bodies 11. Thus, the receiving space S and the supply path 13 may form the flow path for the printing substance P.

Although the supply path 13 is formed in an upper portion of the body unit 10 to fluidly communicate with the receiving space S in FIGS. 1 and 2, the supply path 13 may be formed on a left side or a right side of the body unit 10.

The covers 14 may be connected with the both ends of the pair of bodies 11, so that the receiving space S formed between the pair of bodies 11 is sealed and the printing substance P is prevented from leaking.

The injection unit 20 may inject the printing substance P by fluidly communicating with the flow path formed inside the body unit 10. The injection unit 20 may include a pair of squeeze members 22 that are connected with the pair of bodies 11, respectively, so as to form a nozzle 21. A surface of each squeeze member 22, facing the substrate B, may be a curved surface. Accordingly, interference between the squeeze members 22 and the substrate B or interference between the squeeze members 22 and a mask M disposed on the substrate B may be prevented while a printing operation is being performed.

According to an embodiment of the present disclosure, the squeeze apparatus 1 may inject the printing substance P via the nozzle 21 of the injection unit 20 by passing through the receiving space S when the printing substance P is supplied to the supply path 13 formed between the pair of bodies 11 of the body unit 10 as illustrated in FIG. 2. In this example, an injection force of the printing substance P may be generated by a supply force associated with a provision of the printing substance P to the receiving space S of the body unit 10. That is, when the printing substance P is supplied to the receiving space S, the printing substance P may be pressed in a direction of the nozzle 21 by adjusting the magnitude of an applied pressure and a flow amount for supplying the printing substance P to the receiving space S.

When the printing substance P is injected via the nozzle 21, the printing substance P may be applied to the substrate B in a predetermined pattern via an opening O of the mask M disposed on the substrate B.

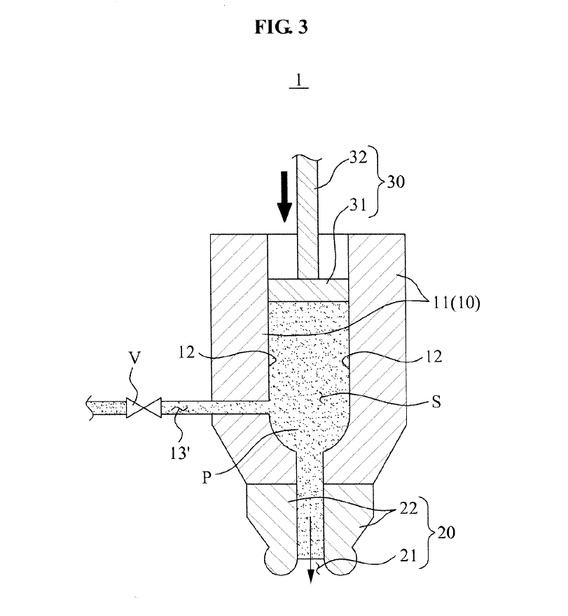

Although FIGS. 1 and 2 illustrates that the printing substance P is injected by a supply force of the printing substance P via the nozzle 21, the printing substance P may be injected by being pressed with an additional pressure unit as illustrated in FIG. 3.

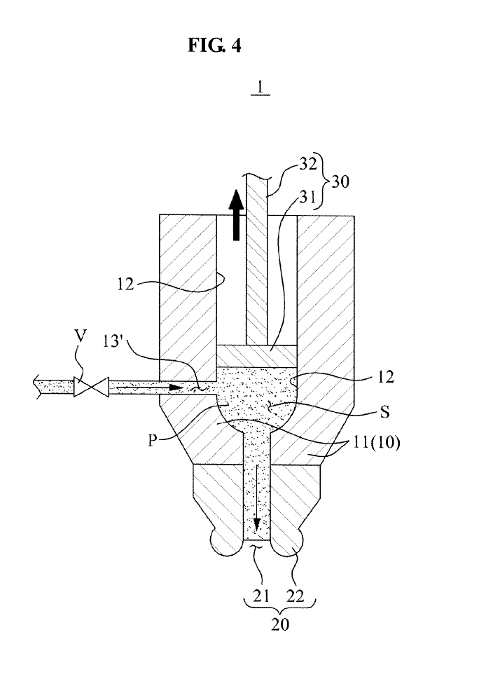

FIG. 3 is a cross-sectional view of a modified squeeze apparatus equipped with a pressure unit 30 according to an embodiment of the present disclosure, and FIG. 4 is a cross-sectional view of the squeeze apparatus of FIG. 3 to which a printing substance is being supplied.

The pressure unit 30 may include a pressure body 31 and a connecting body 32. The pressure body 31, similar to a piston, is provided inside the receiving space S and is brought into close contact with an internal surface of the receiving grooves 12 provided in the pair of bodies 11, and the connecting body 32 connects the pressure body 31 and a driving source (not separately illustrated). The pressure body 31 may press the printing substance P in a direction of the nozzle 21 by a pressurization force transferred through the connecting body 32.

In this example, unlike the supply path 13 of FIGS. 1 and 2, a supply path 13′ may be formed to fluidly communicate with the receiving space S by penetrating one of the pair of bodies 11. Accordingly, when the printing substance P is supplied to the receiving space S through the supply path 13′, the pressure body 31 of the pressure unit 30 may rise in a direction opposite to the direction of the pressure applied to the printing substance P with a supply force. Also, the supply path 13′ may be controlled to be opened and closed by a valve V.

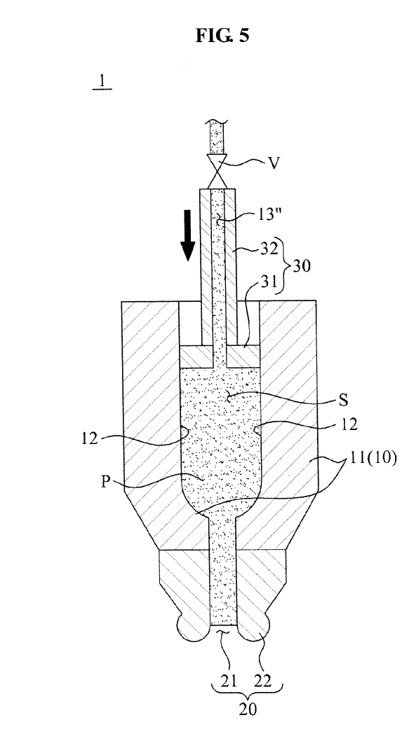

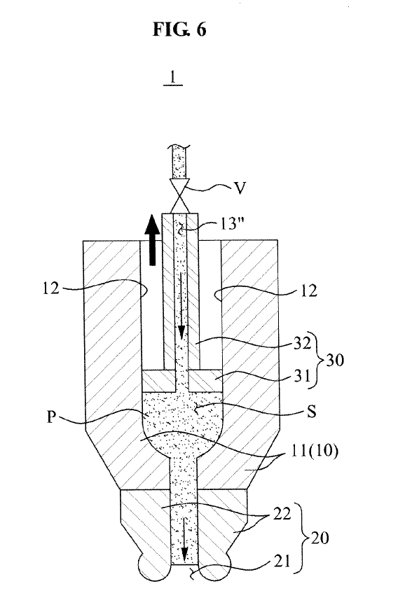

FIG. 5 is a cross-sectional view of a modified squeeze apparatus including a supply path 13″ formed in the pressure unit 30 according to an embodiment of the present disclosure, and FIG. 6 is a cross-sectional view of the squeeze apparatus of FIG. 5 to which a printing substance is being supplied.

Referring to FIG. 5, inside the modified squeeze apparatus may include the supply path 13″. The supply path 13″ is formed by penetrating the pressure body 31 of the pressure unit 30 and the connecting body 32. In this example, the pressure body 31 may press the printing substance P in a direction of the nozzle 21 with a pressurization force transferred through the connecting body 32, as illustrated in FIG. 5. Referring to FIG. 6, when the printing substance P is supplied through the supply path 13″ that fluidly communicates with the receiving space S by penetrating the pressure body 31 and the connecting body 32, the pressure body 31 may rise in a direction opposite to the direction of the pressure applied to the printing substance P with a supply force.

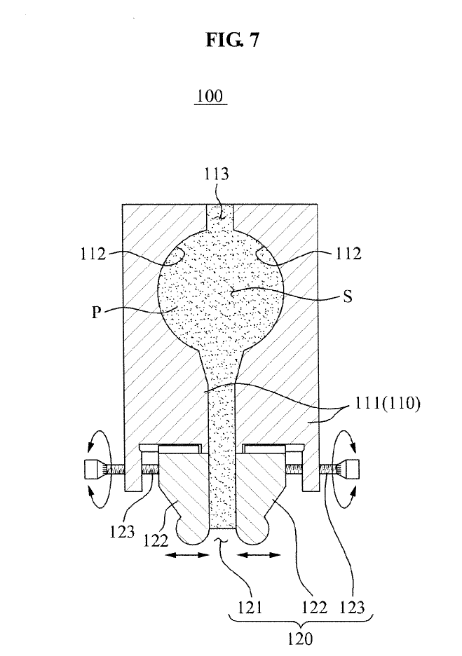

FIG. 7 is a cross-sectional view of a squeeze apparatus according to another embodiment of the present disclosure.

Referring to FIG. 7, a squeeze apparatus 100 may include a body unit 110 and an injection unit 120, similar to the squeeze apparatus 1 of FIG. 2.

The body unit 110 may include a pair of bodies 111 that includes receiving grooves 112, which forms the receiving space S for receiving the printing substance P. The pair of bodies 111 also includes a supply path 113. In this example, although not separately illustrated in detail, the both ends of the body unit 110 may be covered by covers, for example, by the covers 14 of FIG. 1. The configuration of the body unit 110 may be similar to the body unit 10 of FIGS. 1 and 2. Thus, detailed descriptions thereof will be omitted for conciseness.

The injection unit 120 may include a pair of squeeze members 122 respectively connected with the pair of bodies 111 to form the nozzle 121, and an adjusting member 123 to adjust an interval between the squeeze members 122. That is, the squeeze apparatus 100 may adjust a diameter of the nozzle 121 through which the printing substance the printing substance P is injected.

The squeeze members 122 may be installed to be moveable with respect to the bodies 111, and the movement of the squeeze members 122 with respect to the pair of bodies 111 may be adjusted by the adjusting member 123. Similar to a micrometer, the adjusting member 123 may adjust the interval between the pair of squeeze members 122 by moving, through a rotation, the pair of squeeze members 122 installed on the pair of bodies 111, respectively.

An amount of the printing substance P injected through the nozzle 121 and printed on the substrate B as illustrated in FIG. 2 may be adjusted by adjusting the interval between the pair of squeeze members 122. The amount of the printing substance P may be adjusted by adjusting a diameter of the nozzle 121 based on a printing condition or a type of the printing substance P.

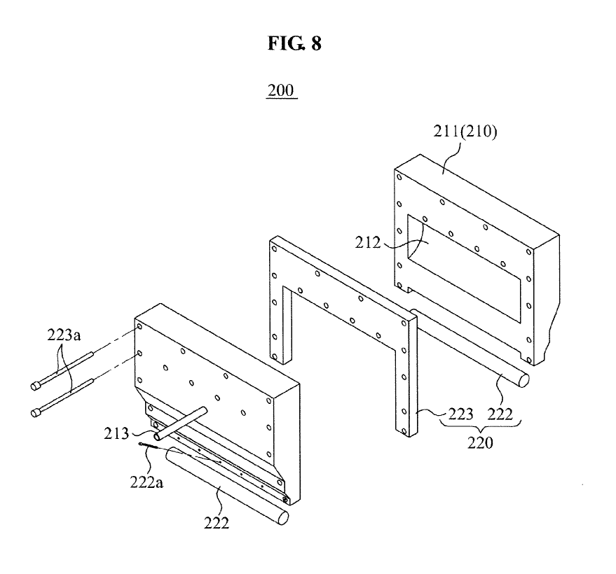

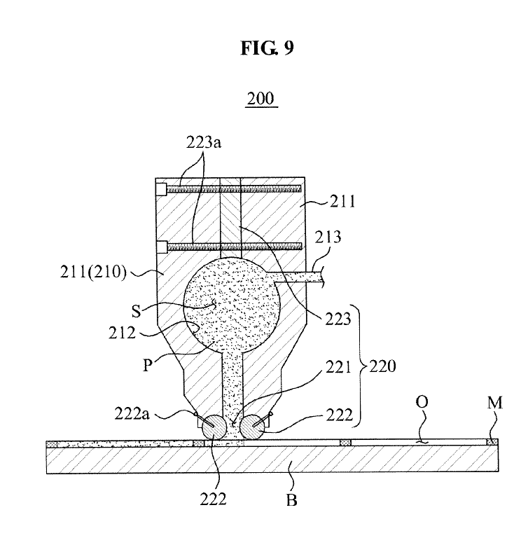

FIG. 8 is an exploded perspective view of a squeeze apparatus according to still another embodiment of the present disclosure, and FIG. 9 is a cross-sectional view of the squeeze apparatus of FIG. 8.

Referring to FIGS. 8 and 9, a squeeze apparatus 200 may include a body unit 210 and an injection unit 220.

The body unit 210 may include a pair of bodies 211, receiving grooves 212, and a supply path 213. In this example, both ends of the pair of bodies 211 may be covered by covers, for example, by the covers 14 of FIG. 1. The both ends of the pair of bodies 211 may not be necessarily covered by the covers when the receiving grooves 212 are formed within the pair of bodies 211. The configuration of the body unit 210 may be similar to the body units of FIG. 1 and FIG. 7 and thus, detailed descriptions thereof will be omitted for conciseness.

The injection unit 220 may include a nozzle 221, a pair of squeeze members 222 forming the nozzle 221, and an adjusting member 223. The pair of squeeze members 222 may be connected with the pair of bodies 111, respectively, using a fastening unit 222a, for example, a bolt and the like. In this example, each squeeze member 222 may have a cylindrical shape of which a cross section is a circular shape. A surface of each squeeze member 222, facing the substrate B, may be a curved surface, as illustrated in FIG. 9.

As illustrated in FIG. 9, the adjusting member 223 may adjust an interval between the pair of bodies 211, so as to adjust an amount of the printing substance P injected to the substrate B via the nozzle 221. That is, the adjusting member 223 may adjust the interval between the pair of squeeze members 222 connected with the pair of bodies 211, respectively, by adjusting the interval between the pair of bodies 211.

Here, the adjusting member 223 may have a plate shape to be connected between the pair of bodies 211, such that the adjusting member 223 does not interfere with the receiving space S. An engaging force of the adjusting member 223 with the pair of bodies 211 may be adjusted using an adjusting bolt 223a, thereby adjusting the interval between the pair of bodies 211.

The interval between the pair of bodies 211 may be adjusted by the adjusting member 223, so that the interval between the pair of squeeze members 222 may be adjusted. Thus, an amount of the printing substance P injected to the substrate B via the opening O of the mask M disposed on the substrate B may be adjusted.

Although the shape of the cross section of the squeeze member 222 is illustrated as a circular shape in FIG. 9, it is not limited thereto.

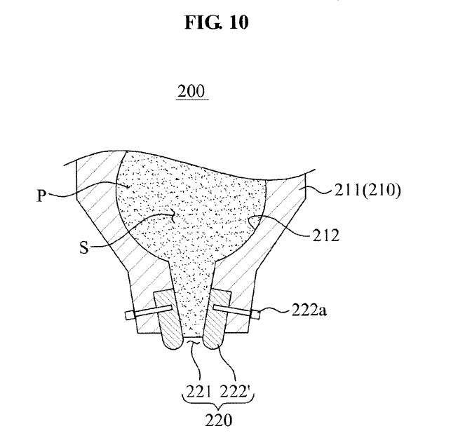

FIG. 10 is a cross-sectional view of a modified squeeze member according to an embodiment of the present disclosure.

Referring to FIG. 10, a pair of modified squeeze members 222′ may face each other and may be connected with the pair of bodies 211, respectively. Each modified squeeze member 222′ may have a cylindrical shape of which an end portion may have a curved surface.

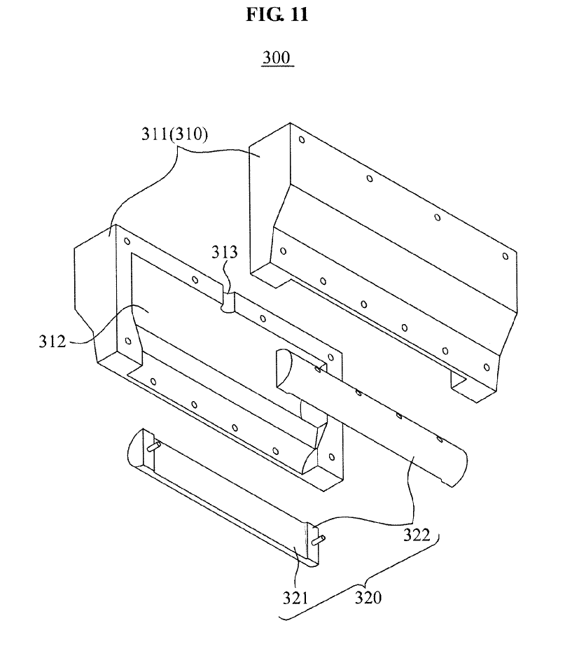

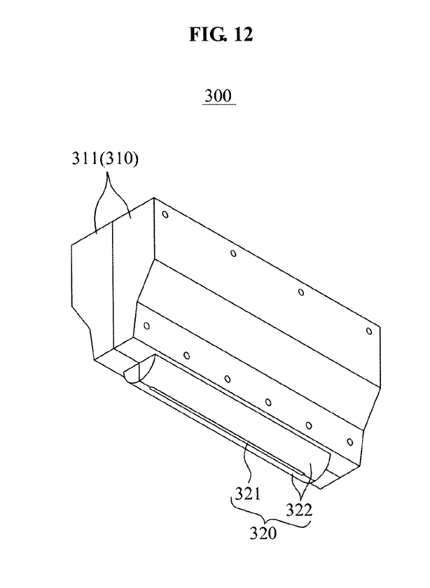

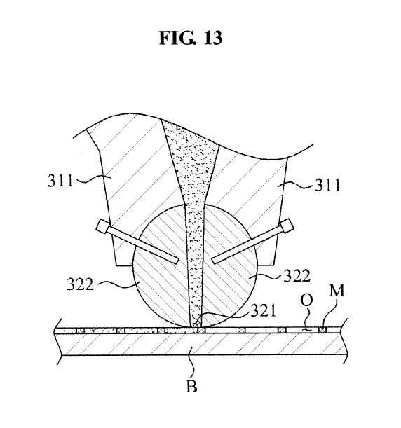

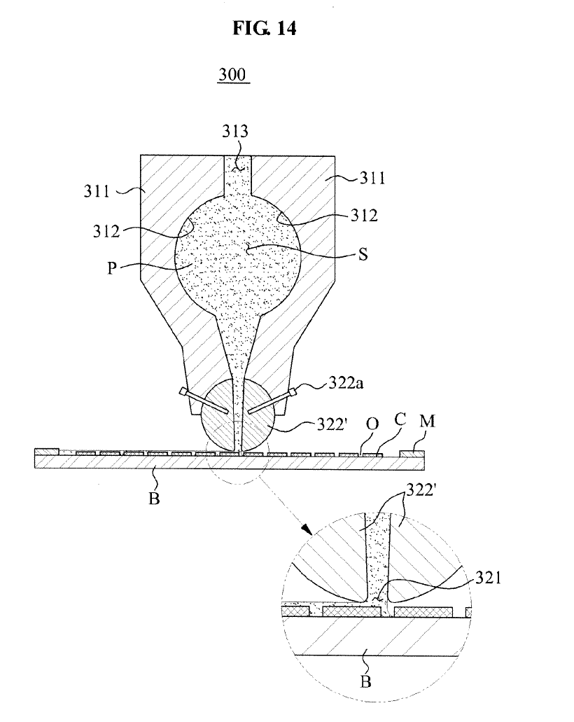

FIG. 11 is an exploded perspective view of a squeeze apparatus according to yet another embodiment of the present disclosure, FIG. 12 is a perspective view of an assembly state of the squeeze apparatus of FIG. 11. FIG. 13 is an expanded cross-sectional view of the squeeze member of FIG. 12. FIG. 14 is a cross-sectional view of a modified squeeze member that is modified from the squeeze member of FIG. 13.

Referring to FIG. 11, a squeeze apparatus 300 may include a body unit 310 and an injection unit 320.

The body unit 310 may include a pair of bodies 311, receiving grooves 312, and a flow path 313. The configuration of the body unit 310 may be similar to the body units of FIGS. 1 through 8 and thus, detailed descriptions thereof will be omitted for conciseness.

The injection unit 320 may include a pair of squeeze members 322 that are connected with the pair of bodies 311, respectively, so as to form a nozzle 321, as illustrated in FIG. 8. Here, each squeeze member 322 has a cylindrical shape, of which a cross section has a semi-circular shape. In this example, to form the nozzle 321 of FIG. 12, a portion of a facing surface of each squeeze member 322 is formed to have a step structure. Also, as illustrated in FIG. 13, the pair of squeeze members 322 are connected with the pair of bodies 311 respectively, using a fastening unit 322a, such that the fastening unit 322a makes an oblique angle with the pair of bodies 311, so as to guide injection of the printing substance P.

Although the squeeze member 322 has a cylindrical shape, of which a cross section has a semi-circular shape, a region of the nozzle 321 is a curved surface as illustrated in FIG. 13. Thus, interference between the squeeze member 322 and the substrate B or the mask M may be prevented.

Referring to FIG. 14, a portion of each squeeze member 322′ (see the magnified portion in FIG. 14), facing the substrate B, may be rounded in a direction toward an internal region of the nozzle 321. With this rounded structure, when the printing substance P, for example, a fluorescent substance, is applied to a chip C via the opening O of the mask M disposed on the substrate B, a uniformly distributed pressure may be applied, thereby preventing a void from being created.

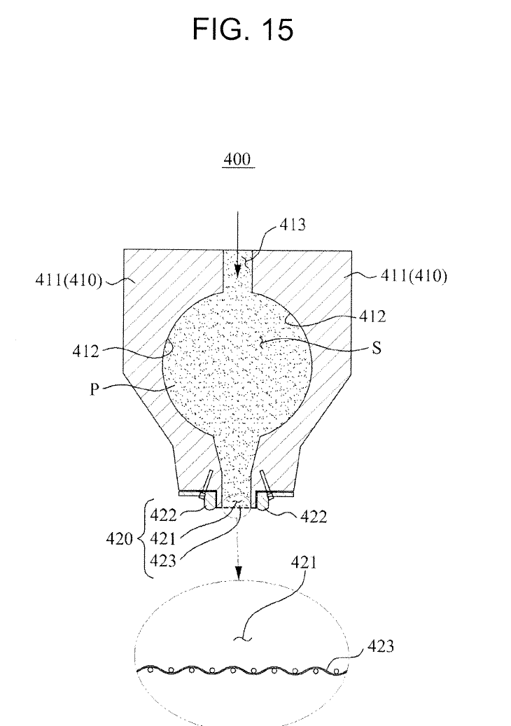

FIG. 15 is a cross-sectional view of a squeeze apparatus according to a further embodiment of the present disclosure.

Referring to FIG. 15, a squeeze apparatus 400 may include a body unit 410 and an injection unit 420.

The body unit 410 may include a pair of bodies 411, which include receiving grooves to form the receiving space S, receiving grooves 412, and a flow path 413. The configuration of the body unit 410 may be similar to the body units of FIGS. 1 through 8 and thus, detailed descriptions thereof will be omitted for conciseness.

The injection unit 420 may inject the printing substance P to the substrate B as illustrated in FIG. 2, and may include a nozzle 421, a pair of squeeze members 422 to be connected with the pair of bodies 411, respectively, to form the nozzle 421, and a mesh member 423 installed in the pair of squeeze members 422. Here, a surface of each squeeze member 422, facing the substrate B (see FIG. 2), may be a curved surface, similar to embodiments as illustrated in FIGS. 1 through 8.

The mesh member 423 may separate the printing substance P injected via the nozzle 421 into a plurality of thin strands. Accordingly, even when a three-dimensional surface has an uneven surface of a great width and/or a great height, the mesh member 423 may inject, without a void, the printing substance P to the three-dimensional surface.

Although the squeeze apparatuses in FIGS. 7 through 15 do not include a pressure unit, the configuration of a squeeze apparatus is not limited thereto, similar to the squeeze apparatus of FIGS. 1 and 2. That is, the squeeze apparatus may be modified to include a pressure unit to press the printing substance P, as illustrated in FIGS. 3 through 6. Also, the squeeze apparatuses of FIGS. 11 through 15 may include an adjusting member, similar to the adjusting member 123 of FIG. 7 and the adjusting member 223 of FIG. 8.

Although embodiments of the present disclosure have been shown and described, it will be appreciated by those skilled in the art that changes may be made without departing from the principles and spirit of the present disclosure, the scope of which is defined in the appended claims.

What is claimed is:

1. A squeeze apparatus, comprising:
a body unit having a flow path inside the body unit for applying a printing substance on a substrate; and
an injection unit having a nozzle that fluidly communicates with the flow path to inject the printing substance,
wherein the nozzle has a curved surface facing the substrate.

2. The apparatus of claim 1, wherein:
to the body unit has a cylinder-shaped receiving space connected to the flow path to receive the printing substance, and
the injection unit is configured to inject the printing substance via the nozzle by a supply force of the printing substance received by the receiving space.

3. The apparatus of claim 1, wherein the body unit comprises:
a receiving space connected to the flow path to receive the printing substance; and
a pressure unit configured to press the printing substance received by the receiving space, in a direction toward the nozzle.

4. The apparatus of claim 3, wherein at least one of the body unit and the pressure unit comprises a supply path fluidly communicating with the receiving space for supplying the printing substance.

5. The apparatus of claim 1, wherein the injection unit is configured to be moveable with respect to the body unit, to adjust an amount of the printing substance injected via the nozzle.

6. The apparatus of claim 1, wherein the injection unit comprises:
a pair of squeeze members facing each other and being movable with respect to the body unit; and
an adjusting member configured to adjust an interval between the pair of squeeze members by moving the pair of squeeze members with respect to the body unit.

7. The apparatus of claim 1, wherein:
the body unit comprises a pair of bodies having respective receiving grooves on facing surfaces of the bodies, the bodies being connectable with each other to provide a receiving space to receive the printing substance, and
the injection unit comprises a pair of squeeze members respectively connectable with the pair of bodies, and an adjusting member configured to adjust an interval between the pair of squeeze members by adjusting an interval between the pair of bodies.

8. The apparatus of claim 1, wherein:
the body unit comprises a pair of bodies, the bodies facing each other and having an interval therebetween to form the flow path for the printing substance; and
the injection unit comprises a pair of squeeze members respectively connectable with the pair of bodies, each squeeze member having a cylindrical shape of which a cross section has a circular shape or a semi-circular shape.

9. The apparatus of claim 1, wherein:
the body unit comprises a pair of bodies, the bodies facing each other and having an interval therebetween form the flow path for the printing substance; and
the injection unit comprises a pair of squeeze members respectively connectable with the pair of bodies, each squeeze member having a cylindrical shape, of which a cross section has a semi-circular shape, an end portion of each squeeze member facing the substrate and having a rounded shape in a direction toward an internal region of the nozzle.

10. The apparatus of claim 1, wherein:
the body unit comprises a pair of bodies, the bodies facing each other and having an interval therebetween to form the flow path for the printing substance; and
the injection unit comprises a pair of squeeze members respectively connectable with the pair of bodies, each squeeze member having a cylindrical shape, an end portion of each squeeze member facing the substrate and having a curved surface.

11. The apparatus of claim 1, wherein the injection unit comprises a mesh member disposed in the nozzle.

12. A squeeze apparatus, comprising:
a body unit having a flow path inside the body unit for applying a printing substance to a substrate; and
an injection unit including a pair of squeeze members and configured to inject the printing substance, the squeeze members being disposed in the body unit and having an interval therebetween to form a nozzle that fluidly communicates with the flow path,
wherein each squeeze member has a curved surface facing the substrate.

13. The apparatus of claim 12, wherein:
the body unit comprises a pair of bodies connectable with each other, the bodies including a pair of squeeze members respectively disposed in the pair of bodies, and having receiving grooves in facing surfaces thereof to form a receiving space for receiving the printing substance, and
the printing substance is injected via the nozzle by a supply force of the printing substance received by the receiving space.

14. The apparatus of claim 12, wherein the body unit comprises:
a pair of bodies connectable with each other, the bodies including a pair of squeeze members respectively disposed in the pair of bodies, and having receiving grooves in facing surfaces thereof to form a receiving space for receiving the printing substance; and
a pressure unit configured to press the printing substance received by the receiving space in a direction toward the nozzle.

15. The apparatus of claim 14, wherein at least one of the body unit and the pressure unit comprises a supply path fluidly communicating with the receiving space for supplying the printing substance.

16. The apparatus of claim 12, wherein the pair of squeeze members are configured to adjust the interval between the squeeze members with respect to the body unit, so that an amount of the printing substance injected via the nozzle is adjusted.

17. The apparatus of claim 12, wherein:
the body unit comprises a pair of bodies connectable with each other, the bodies including a pair of squeeze members respectively disposed in the pair of bodies and having receiving grooves in facing surfaces thereof to form a receiving space for receiving the printing substance, and
the injection unit comprises an adjusting member configured to adjust an interval between the pair of bodies to adjust the interval between the pair of squeeze members.

18. The apparatus of claim 12, wherein each squeeze member has a cylindrical shape of which a cross section has a circular shape or a semi-circular shape.

19. The apparatus of claim 12, wherein:
each squeeze member has a cylindrical shape of which a cross section has a semi-circular shape, and
an end portion of each squeeze facing the substrate has a rounded shape in a direction toward an internal region of the nozzle.

20. The apparatus of claim 12, wherein:
each squeeze member has a cylindrical shape,
an ending portion of each squeeze member facing the substrate has a curved surface, and
the injection unit comprises a mesh member disposed between the pair of squeeze members.
